(19) United States
(12) Patent Application Publication
(10) Pub. No.: US 2026/0136887 A1
(43) Pub. Date: May 14, 2026

(54) METHOD FOR PROCESSING A BONDED WAFER

(71) Applicant: DISCO CORPORATION, Tokyo (JP)

(72) Inventors: Hayato Tanaka, Tokyo (JP); Hayato Iga, Tokyo (JP); Akira Mizutani, Tokyo (JP); Kazuya Hirata, Tokyo (JP); Taku Iwamoto, Tokyo (JP)

(21) Appl. No.: 19/385,758

(22) Filed: Nov. 11, 2025

(30) Foreign Application Priority Data
Nov. 13, 2024 (JP) 2024-197789

(51) Int. Cl. H01L 23/00; H01L 21/683

(52) U.S. Cl. CPC H10P 72/7402; H10P 72/7412; H10P 72/744; H10W 72/0198; H10W 80/211

(57) ABSTRACT

A method for processing a bonded wafer including a first wafer where a first device is formed on a front surface side of a first substrate thereof and a second wafer bonded together, to transfer the first device to the second wafer by separating a first substrate side of the bonded wafer therefrom, includes a laser processing step including forming a processed layer planarly within the first wafer by emitting a laser beam having a wavelength transmissive through the first substrate toward the bonded wafer from a back surface of the first wafer to be focused within the first substrate at a position in vicinity of a bonded surface between the first wafer and the second wafer; and a separation step including separating the first substrate side from the second wafer by splitting at the processed layer, with the first device remaining bonded to the second wafer.

### CROSS REFERENCE TO RELATED APPLICATION

This application is based upon and claims the benefit of priority from the prior Japanese Patent Application No. 2024-197789 filed on Nov. 13, 2024; the entire contents of which are incorporated herein by reference.

### FIELD

The present disclosure relates to a method for processing a bonded wafer in which devices on wafer are transferred onto another wafer.

### BACKGROUND

Japanese Patent Application Laid-Open Publication No. 2024-062595 discloses a method, in which one of two wafers forming a bonded wafer bonded with a bonding film is ground, and devices on the one of the wafers are transferred onto the other wafer. Through the grinding process performed in this method, approximately 10 μm of the one wafer may remain unground, and a thickness of a stacked wafer in which the devices are transferred may be increased accordingly. Moreover, depending on the wafer grinding process, often approximately 760 μm of the wafer is removed, which causes a problem such that a longer processing time is required.

Meanwhile, Japanese Patent Application Laid-Open Publication No. 2021-006352 discloses a method for separating one of the wafers by forming a separable layer in a buffer layer with a laser beam. According to this publication, the grinding process performed in the above-mentioned Japanese Patent Application Laid-Open Publication No. 2024-062595 may be omitted, thereby shortening the processing time.

### SUMMARY

However, according to the method disclosed in Japanese Patent Application Laid-Open Publication No. 2021-006352, in order to inhibit damage to the devices on the wafer that may be caused by leaked light from the emitted laser beam transmitting through the bonding film, the bonding film needs to be thickened, and accordingly, productivity may be lowered.

The present disclosure is made in view of such circumstances, and one object thereof is to provide a method for processing a bonded wafer capable of improving productivity.

According to an aspect of the present disclosure, a method for processing a bonded wafer, including a first wafer on which a first device is formed on a front surface side of a first substrate thereof and a second wafer bonded together, to transfer the first device to the second wafer by separating a first substrate side of the bonded wafer therefrom, includes a laser processing step including forming a processed layer planarly within the first wafer by emitting a laser beam having a wavelength transmissive through the first substrate toward the bonded wafer from a back surface of the first wafer to be focused within the first substrate at a position in vicinity of a bonded surface between the first wafer and the second wafer; and a separation step including separating the first substrate side from the second wafer by splitting at the processed layer, with the first device from the first wafer remaining bonded to the second wafer.

According to the present disclosure, the processed layer is formed within the first wafer to split the bonded wafer thereat, and with the first device from the first wafer remaining bonded to the second wafer, the first substrate side is separated; therefore, necessity of laser processing to a bonding layer, bonding film, or bonding member before the separation may be eliminated. Accordingly, necessity for forming a thick bonding film to prevent damage to the device due to leakage of the light from the laser beam irradiating the conventional bonding film, and the like, may be eliminated, thereby improving productivity.

### BRIEF DESCRIPTION OF THE DRAWINGS

FIG. 1A illustrates a preparation step, FIG. 1B illustrates a bonding step, FIG. 1C illustrates a laser processing step, and FIG. 1D illustrates a separation step in a method for manufacturing a stacked wafer according to a first embodiment.

FIG. 2 is a schematic perspective view of a laser processing apparatus.

FIGS. 3A and 3B are explanatory diagrams illustrating processed marks to be formed in the laser processing step.

FIGS. 4A, 4B, and 4C are explanatory diagrams illustrating processed marks to be formed in the laser processing step.

FIG. 5 is an explanatory cross-sectional view illustrating a state during formation of a processed layer in the laser processing step.

FIG. 6 is an explanatory diagram of a processed layer treatment step according to the method for manufacturing a stacked wafer.

FIGS. 7A-7D are explanatory diagrams of steps, which are similar to the steps shown in FIGS. 1A-1D, in a method for manufacturing a stacked wafer according to a second embodiment.

FIGS. 8A-8D are explanatory diagrams of steps, which are similar to the steps shown in FIGS. 1A-1D, in a method for manufacturing a stacked wafer according to a third embodiment.

FIG. 9 is a cross-sectional view illustrating a laser processing step, which is similar to that shown in FIG. 5, according to the third embodiment.

FIGS. 10A-10D are explanatory diagrams of steps, which are similar to the steps shown in FIGS. 1A-1D, in a method for manufacturing a stacked wafer according to a fourth embodiment.

FIGS. 11A-11D are explanatory diagrams of steps, which are similar to the steps shown in FIGS. 1A-1D, in a method for manufacturing a stacked wafer according to a fifth embodiment.

FIG. 12 is a cross-sectional view illustrating a laser processing step, which is similar to that shown in FIG. 5, according to the fifth embodiment.

FIG. 13 is a cross-sectional view illustrating a laser processing step, which is similar to that shown in FIG. 5, according to the fifth embodiment.

### DESCRIPTION OF EMBODIMENTS

### First Embodiment

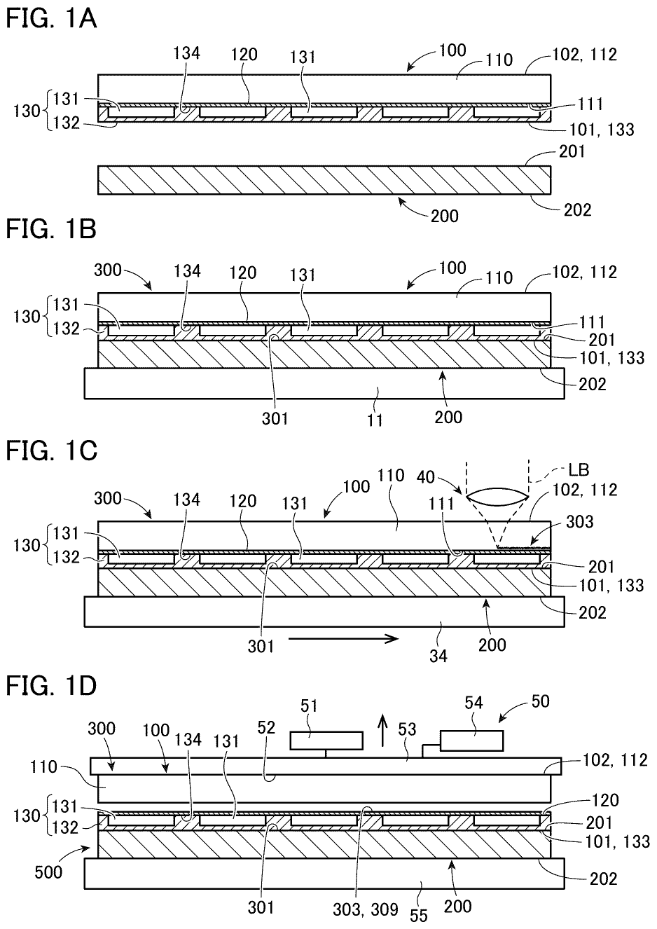

Hereinafter, with reference to the accompanying drawings, a method for manufacturing a stacked wafer including a method for processing a bonded wafer according to a first embodiment will be described. FIG. 1A illustrates a preparation step, FIG. 1B illustrates a bonding step, FIG. 1C illustrates a laser processing step, and FIG. 1D illustrates a separation step. It should be noted that the steps shown in the drawings in the first embodiment are merely examples, and the present disclosure is not limited to this configuration. Further, in the drawings including FIGS. 1A-1D, hatching on a cross section of a first substrate 110, which will be described later, is omitted.

### Preparation Step

The preparation step is a preparation for forming a bonded wafer 300 (see FIG. 1B) and a stacked wafer 500 (see FIG. 1D), and a first wafer 100 and a second wafer 200, as shown in FIG. 1A, each having a disk shape are prepared. The first wafer 100 includes a front surface 101 and a back surface 102, which are planes orthogonal to a thickness direction. The first wafer 100 is disposed in an orientation such that the front surface 101 faces downward in FIG. 1A and the back surface 102 faces upward in FIG. 1A. The second wafer 200 includes a front surface 201 and a back surface 202, which are planes orthogonal to a thickness direction. The second wafer 200 is disposed in an orientation such that the front surface 201 faces upward in FIG. 1A and the back surface 202 faces downward in FIG. 1A.

The first wafer 100 includes a first substrate 110 (substrate) formed of silicon, an insulating film 120 formed on a front surface 111, which forms a surface on one side in a thickness direction of the first substrate 110, and a first device layer 130 formed on a front surface (lower surface in FIG. 1A) of the insulating film 120. The back surface 102 of the first wafer 100 is formed of a back surface 112 of the first substrate 110. The insulating film 120 is an interlayer insulating film laminated between the first substrate 110 and the first device layer 130. The insulating film 120 may be any of a silicon oxide film (SiO2 film), a silicon carbide film (SiC film), a silicon nitride film (SiN film), or a silicon carbonitride film (SiCN film).

The first device layer 130 includes a plurality of first devices 131 (device) and a first surface film 132 which is formed as an insulating film. The front surface 101 of the first wafer 100 is formed of a front surface 133 of the first surface film 132 in the first device layer 130, and on the front surface 101 side of the first wafer 100, first devices 131 are formed.

Each of the plurality of first devices 131 includes an element for composing, for example, an IC, a semiconductor memory, or an image sensor. The plurality of first devices 131 are formed in a plurality of regions partitioned by a plurality of streets 134 formed in a grid pattern.

The first surface film 132 may be any of a silicon oxide film (SiO2 film), a silicon carbide film (SiC film), a silicon nitride film (SiN film), or a silicon carbonitride film (SiCN film).

The second wafer 200 has an outer shape corresponding to that of the first wafer 100, and may be, for example, formed in the disk shape similar to that of the first wafer 100. For the second wafer 200, for example, a wafer the same as the first wafer 100, but before the first device layer 130 is formed thereon, may be used. However, the second wafer 200 is not limited to this. In other words, the second wafer 200 may have a device layer formed thereon similarly to the first wafer 100.

In the preparation step, as preparation for the bonding step using plasma-activated bonding, preparation for enabling the front surface 201 of the second wafer 200 to be bonded to the front surface 101 of the first wafer 100 (the front surface 133 of the first surface film 132) is performed.

In the preparation step, for example, plasma of a rare gas generated by using a rare gas and high-frequency power is emitted at each of the front surface 133 of the first surface film 132 of the first wafer 100 and the front surface 201 of the second wafer 200. As a result, the front surface 101 of the first wafer 100 (the front surface 133 of the first surface film 131) and the front surface 201 of the second wafer 200 are activated so that the front surfaces 101, 201 are enabled to function as bonding members in the bonding step.

### Bonding Step

After the preparation step is completed, the bonding step is performed with plasma-activated bonding, as shown in FIG. 1B. In the bonding step, the second wafer 200 is held on a chuck table 11 with the back surface 202 facing downward, and thereafter, the first wafer 100 is placed to face the second wafer 200 such that the front surface 101, which forms the first device layer 130 side of the first wafer 100, faces the front surface 201.

Thereafter, the front surface 101 of the first wafer 100 is pressed against the front surface 201 of the second wafer 200. Accordingly, the front surfaces 101, 201 of the first wafer 100 and the second wafer 200, respectively, which function as the bonding members, are bonded, thereby forming a bonded wafer 300. As such, the front surfaces 101, 201 of the first wafer 100 and the second wafer 200, respectively, which are bonded to each other, form a bonding surface 301 in the bonded wafer 300. Note that bonding of the first wafer 100 and the second wafer 200 is not limited to direct bonding such as surface-activated bonding, but may be bonding via an intermediate layer such as adhesive bonding or glass-fit bonding.

### Laser Processing Step

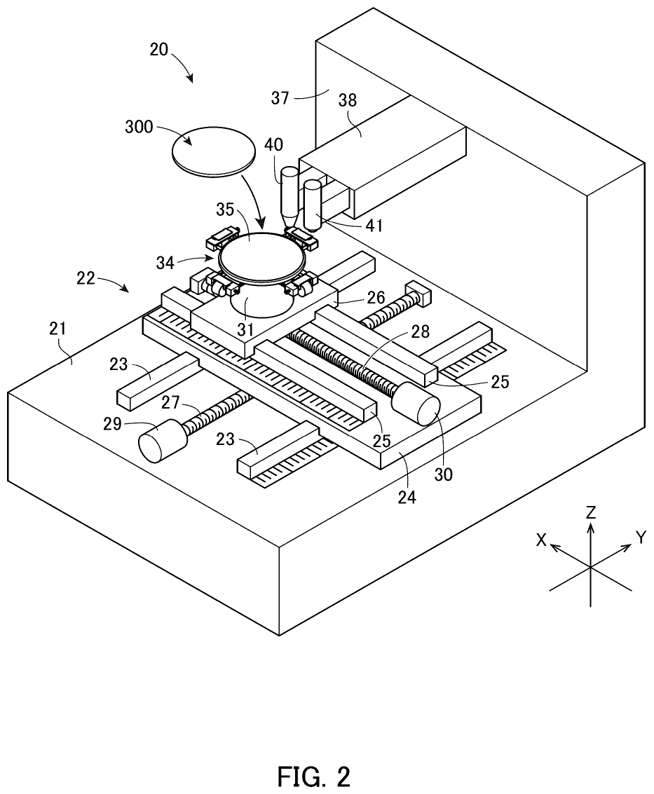

After the bonding step is completed, the laser processing step is performed with a laser processing apparatus 20. FIG. 2 is a schematic perspective view of a laser processing apparatus. Hereinafter, the laser processing apparatus will be described with reference to FIG. 2. Note that the laser processing apparatus may have any configuration capable of performing the laser processing step according to the present embodiment and is not limited to the configuration shown in FIG. 2.

As shown in FIG. 2, the laser processing apparatus 20 is configured to process the bonded wafer 300 with laser by relatively moving a laser emitter 40 emitting a laser beam LB (see FIG. 1C) and a holder table 34 holding the bonded wafer 300.

On a base 21 of the laser processing apparatus 20, a holder table moving mechanism 22 for moving the holder table 34 in an X-axis direction and a Y-axis direction is provided. The holder table moving mechanism 22 includes a pair of guide rails 23 disposed on the base 21 in parallel to the Y-axis direction, and a Y-axis table 24, which is drivable by a motor and slidably mounted on the pair of guide rails 23. The holder table moving mechanism 22 further includes a pair of guide rails 25 disposed on an upper surface of the Y-axis table 24 in parallel to the X-axis direction, and an X-axis table 26, which is drivable by a motor and slidably mounted on the pair of guide rails 25.

On rear sides of the Y-axis table 24 and the X-axis table 26, threaded portions (not shown) are formed, and ball screws 27, 28 are screwed into the respective threaded portions. When driving motors 29, 30 connected to ends of the ball screws 27, 28, respectively, are rotationally driven, the holder table 34 is moved along the guide rails 23, 25 in the X-axis direction and the Y-axis direction.

The holder table moving mechanism 22 further includes a rotation mechanism 31 provided on the X-axis table 26. The rotation mechanism 31 supports the holder table 34 from below, and the rotation mechanism 31 and the holder table 34 are moved together along with the X-axis table 26 in the X-axis direction and the Y-axis direction. Further, the rotation mechanism 31 includes a rotation bearing, a driving motor, and a pulley mechanism, which are not shown, and the holder table 34 is rotated about a Z-axis. On an upper surface of the holder table 34, a holder surface 35 for holding the bonded wafer 300 by suction is formed.

On an upright wall 37 located rearward from the holder table 34, a protruding arm portion 38 is provided, and at a tip end of the arm portion 38, the laser emitter 40 and an image-capturing camera 41 are provided so as to face the holder table 34 in a vertical direction. The laser emitter 40 emits the laser beam LB (see FIG. 1C) oscillated from a laser oscillator, which is not shown, toward the bonded wafer 300 held on the holder table 34. The image-capturing camera 41 is provided sideward from the laser emitter 40 to capture an image of the surface of the bonded wafer 300 held on the holder table 34.

Using this laser processing apparatus 20, the laser processing step as shown in FIG. 1C is performed. In the laser processing step, the bonded wafer 300 is conveyed onto the holder table 34 by a conveyer, which is not shown. Subsequently, the laser emitter 40 emits the laser beam LB having a wavelength transmissive through the first substrate 110 of the first wafer 100 in pulses from the back surface 102 of the first wafer 100 to irradiate the bonded wafer 300. In other words, the laser beam LB emitted from the laser emitter 40 irradiates the wafer from a first substrate 110 side (back surface 102 side) of the first wafer 100.

The laser beam LB to be emitted is adjusted by a focusing lens in the laser emitter 40 so as to be focused within the first wafer 100 at a position in the vicinity of the bonded surface 301 between the first wafer 100 and the second wafer 200. More specifically, the focusing position of the laser beam LB in the bonded wafer 300 is set at a position within the first substrate 110 in the first wafer 100, shifted from the front surface 111 toward the back surface 112 of the first substrate 110 but in the vicinity of the front surface 111. Moreover, the focusing position is adjusted in the thickness direction of the first wafer 100 such that a distance to the front surface 101 is shorter than a distance to the back surface 102 of the first wafer 100.

By focusing the laser beam LB within the thickness of the first substrate 110 in the first wafer 100, a portion of the first substrate 110 at which the laser beam LB is focused is modified from single crystal to polycrystalline, and a volume thereof expands, whereby a processed layer 303 (processed mark 304) is formed in the first substrate 110 in the first wafer 100.

The laser beam LB used in the laser processing step is set to have the wavelength λ within a range from 1000 nm to 3000 nm, inclusive, and more preferably, set to have the wavelength λ of 1342 nm. By setting the wavelength λ to such a value, the laser beam LB is enabled to transmit the first substrate 110 of the first wafer 100 while energy of the laser beam LB may be efficiently absorbed at the focusing position.

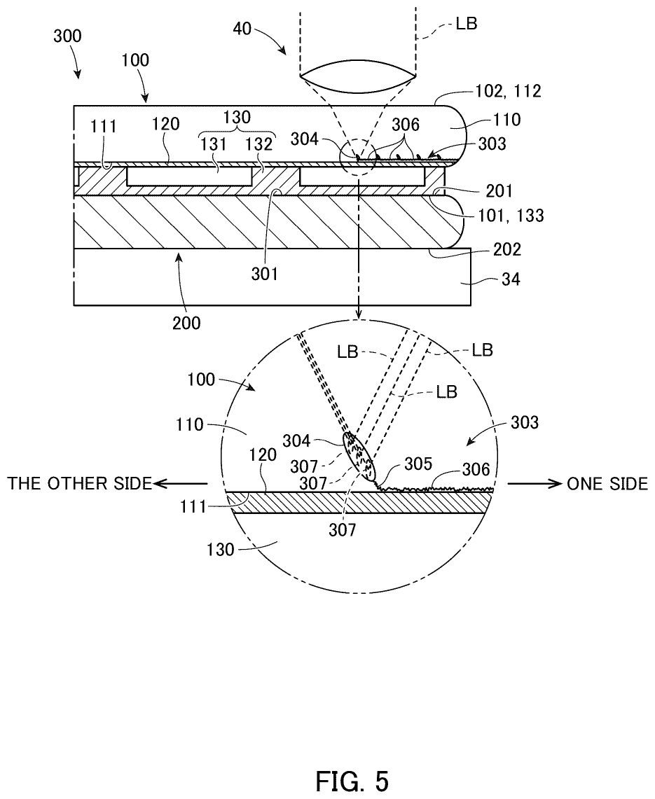

In the laser processing step, while the laser beam LB is emitted, the holder table 34 holding the bonded wafer 300 is moved relative to the laser emitter 40 along a horizontal direction (direction parallel to an XY plane in FIG. 2). Accordingly, the bonded wafer 300 is irradiated with the laser beam LB over the entire area as viewed in the thickness direction. By irradiation with this laser beam LB, the processed mark 304 is formed in the first substrate 110 in the first wafer 100, and a first crack 305 and a second crack 306 (see FIG. 5) are developed from the expanded processed mark 304, thereby forming the processed layer 303 planarly within the thickness of the first wafer 100.

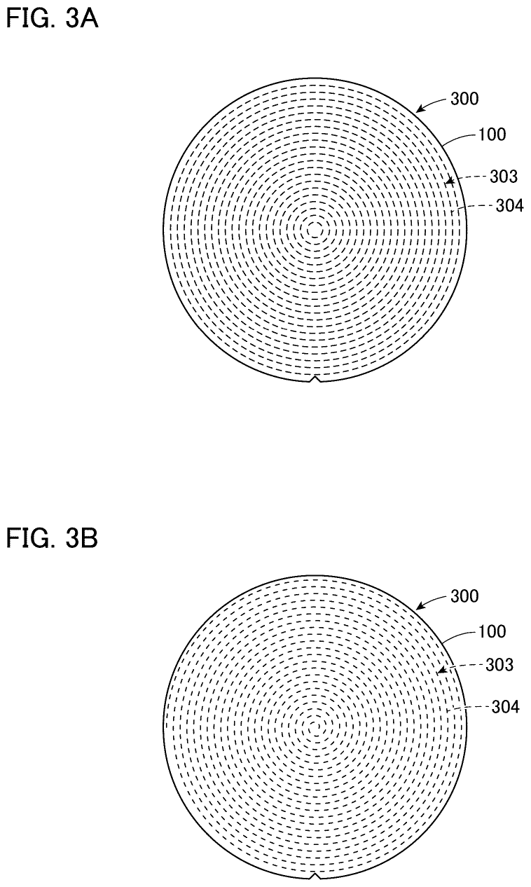

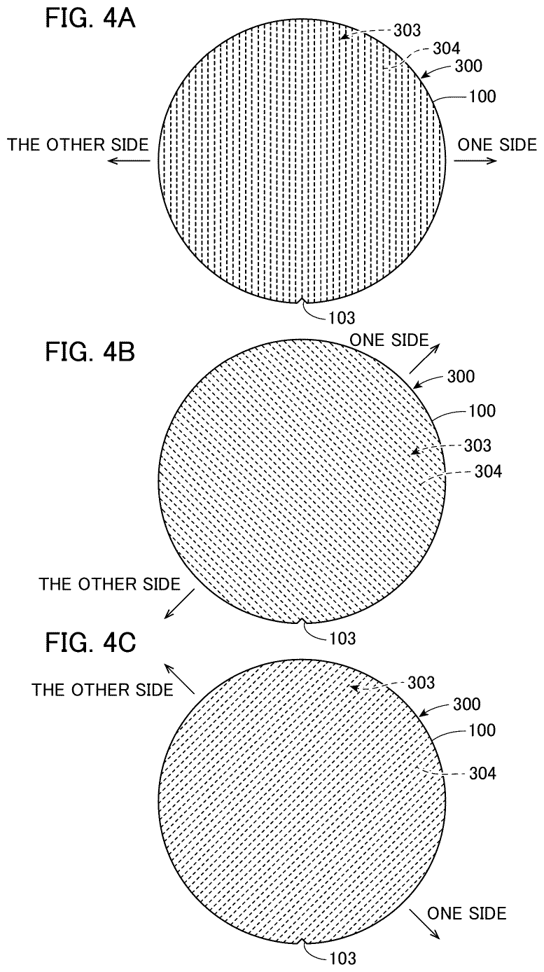

FIGS. 3A, 3B, 4A, 4B, and 4C are explanatory diagrams illustrating processed marks 304 formed by laser irradiation in the laser processing step, viewed from above the first wafer 100. In the laser processing step, by relatively moving the laser emitter 40 with respect to the bonded wafer 300 held on the holder table 34, the wafer is irradiated with the laser beam LB along paths as indicated by broken lines in FIGS. 3A, 3B, 4A, 4B, and 4C. At the irradiated locations, processed marks 304 are formed, thereby forming the planar processed layer 303 within the first wafer 100.

In the laser processing step, for forming the planar processed layer 303 shown in FIG. 3A, the laser beam LB is emitted along a plurality of concentric circles centered on a center of the first wafer 100. Specifically, the laser beam LB is emitted first in a circular path along an outermost circle on the first wafer 100, and sequentially along concentric circles while gradually reducing a diameter of the circle. By irradiation with this laser beam LB, a plurality of concentric processed marks 304 are created to form the processed layer 303. The processed marks 304 formed by being irradiated with the laser beam LB are each in an ellipsoidal shape in a cross-sectional view (see FIG. 5). More specifically, each processed mark 304 is an ellipsoidal shape with a lower end located toward the outer periphery and an upper end inclined toward the center. The plurality of concentric processed marks 304 formed by irradiation with the laser beam LB are formed from larger circles to smaller circles sequentially. In other words, by irradiation with the laser beam LB, circular processed marks 304 are sequentially formed from the outer periphery, which is on one side in a planar direction on the first substrate 110 (the first wafer 100), toward the center, which is on the other side in the planar direction, thereby forming the planar processed layer 303.

FIG. 5 is an explanatory cross-sectional view illustrating a state during formation of the processed layer in the laser processing step. In the processed layer 303, in the process where the processed marks 304 are being formed in the concentric arrangement in a view from above, the first crack 305 developing obliquely from a lower end of each processed mark 304 toward the insulating film 120 in the thickness direction and toward the outer periphery, as shown in FIG. 5, is formed within the first substrate 110.

Further, the second crack 306 in the processed layer 303 is developed from the first crack 305 reaching the insulating film 120, extending planarly along the planar direction of the front surface 111 of the first substrate 110. Specifically, the first crack 305 reaching the insulating film 120 develops to be the second crack 306 extending in a radial direction of the first wafer 100 toward the outer periphery at the boundary between the first substrate 110 and the insulating film 120. Moreover, in a circumferential direction of the first wafer 100, the second cracks 306 developed from adjacent processed marks 304 are connected. As such, a plurality of second cracks 306 extend in parallel to the bonded surface, which is the boundary between the first substrate 110 and the insulating film 120, and develop planarly in the planar direction of the first wafer 100. In other words, in the first wafer 100, the second cracks 306 are formed planarly along the bonded surface, which is the boundary between the first substrate 110 and the insulating film 120, where the first substrate 110 and the insulating film 120 are bonded by a force weaker than the intermolecular bonding force of silicon of the first substrate 110.

In the laser processing step, for forming the planar processed layer 303 as shown in FIG. 3B, the laser beam LB is emitted along a swirl centered on the center of the first wafer 100. By emitting the laser beam LB in the manner, processed marks 304 in a swirl are formed to create the processed layer 303. This processed marks 304 are formed from the outer periphery, which is on one side in the planar direction of the first wafer 100, toward the center, which is on the other side in the planar direction, and each is in an ellipsoidal shape in a cross-sectional view, with a lower end located toward the outer periphery and an upper end inclined toward the center (see FIG. 5). In the process for forming the processed marks 304 swirly, as in the above case of forming the plurality of concentric processed marks 304, a first crack 305 is formed obliquely from each processed mark 304 within the first substrate 110 (see FIG. 5). Further, the first crack 305 reaching the insulating film 120 develops to be the second crack 306, which extends between the first substrate 110 and the insulating film 120 and is connected with another. As such, the second cracks 306 are formed planarly along the bonded surface, which is the boundary between the first substrate 110 and the insulating film 120. Note that when forming the processed marks 304 concentrically or swirly, the processed marks 304 are formed at equal intervals in the circumferential direction.

In the laser processing step, when forming the planar processed layers 303 as shown in FIGS. 4A, 4B, and 4C, the laser beam LB is emitted along a plurality of lines (linearly) that are parallel to one another. By emitting the laser beam LB in the manner, the plurality of processed marks 304 aligning linearly in a view from above are formed to create the processed layer 303. The processed marks 304 are each in an ellipsoidal shape in a cross-sectional view, in which a lower end is located toward the outer periphery and an upper end inclines toward the center (see FIG. 5). The linear processed marks 304 are sequentially formed from one side toward the other in the planar direction of the first wafer 100. More specifically, the linear processed marks 304 are sequentially formed from one side toward the other side in the planar direction, where one of the outer peripheral sides on a diameter orthogonal to the aligning direction of the processed marks 304 is defined as one side in the planar direction of the first wafer 100, and the other of the outer peripheral sides is defined as the other side in the planar direction of the first wafer 100.

In the process for forming the processed mark 304, the first crack 305 is formed within the first substrate 110 from a tip (lower end) of the inclined processed mark 304 toward the insulating film 120. As the first crack 305 reaches the insulating film 120, the crack develops to be the second crack 306 and extends in the radial direction of the first wafer 100 toward the outer periphery at the boundary between the first substrate 110 and the insulating film 120. Further, in the circumferential direction of the first wafer 100, adjacent second cracks 306 are connected. As such, the plurality of second cracks 306 develop in parallel to the bonded surface, which is the boundary between the first substrate 110 and the insulating film 120, and are formed planarly along the planar direction of the first wafer 100.

In the bonded wafer 300 shown in FIG. 4A, the plurality of linear processed marks 304 aligned in parallel are formed in a diametrical direction connecting a notch 103 and a center of the first wafer 100. Note that, for forming one linear processed mark 304, the laser beam LB may be emitted in either direction from one side toward the other side or from the other side toward the one side in the linear direction.

In the bonded wafers 300 shown in FIGS. 4B and 4C, the plurality of linear processed marks 304 are formed in a diametrical direction inclined by 45 degrees with respect to the diameter connecting the notch 103 and the center of the first wafer 100. In the bonded wafers 300 shown in FIGS. 4B and 4C, similarly to the processed layer 303 formed in the bonded wafer 300 shown FIG. 4A, the processed layer 303 is formed by forming the processed marks 304, the first cracks 305, and the second cracks 306. Between FIG. 4B and FIG. 4C, directions of the plurality of linear processed marks 304 inclined by 45 degrees with respect to the diameter connecting the notch 103 and the center of the first wafer 100 are opposite.

As shown in FIG. 5, in the laser processing step, due to the processed marks 304 being formed the first crack 305 and the second crack 306 expand in volume, and by the resulting impact, the cracks 305, 306 develop toward portions where the bonding strength is weak.

The processed marks 304 in the processed layer 303 may be formed by emitting the laser beam LB, which is split by the laser emitter 40 into a plurality of beams, toward a plurality of focusing positions 307. Further, the processed marks 304 are each formed in an ellipsoid shape in a cross-sectional view, extending in a direction connecting the plurality of focusing positions 307. The extending direction of the processed mark 304 is adjusted so that the extending direction inclines with respect to the thickness direction of the first wafer 100. This inclining direction is set to extend from the back surface 102, which is the non-bonded surface opposite to the bonded surface 301 in the first wafer 100, toward the bonded surface 301, obliquely from the other side toward one side in the planar direction of the bonded surface 301. In this context, the direction from the back surface 102 toward the bonded surface 301 is the direction from top to bottom in FIG. 5, and when the laser beam LB is emitted in the manner as shown in FIGS. 3A and 3B, the direction from the other side toward the one side in the planar direction of the bonded surface 301 is the direction from left to right in FIG. 5. Therefore, the extending direction of the processed mark 304 that inclines obliquely is the direction shifting from left toward right as the processed mark 304 extends from top to bottom in FIG. 5.

### Separation Step

After the laser processing step is completed, the separation step as shown in FIG. 1D is performed. In the separation step, the bonded wafer 300 is conveyed to and held on a chuck table 55 of a separating apparatus 50 by a conveyer, which is not shown. Next, a suction pad 53 connected to a suction source 51 generates a negative pressure on a holder surface 52 to hold the back surface 102 of the first wafer 100 in the bonded wafer 300. Further, by lifting the suction pad 53 via a lift/lower mechanism 54, a force to separate the first wafer 100 from the second wafer 200 is applied to the bonded wafer 300. Accordingly, in the bonded wafer 300, the first substrate 110 in the first wafer 100 is split from the first device layer 130 at the planar second cracks 306 in the processed layer 303.

In the separation step, by being split at the second cracks 306 in the processed layer 303, a portion of the first wafer 100 toward the back surface 102 side with respect to a splitting surface 309 is separated from the second wafer 200. In the meantime, a portion of the first wafer 100 toward the front surface 101 side with respect to the splitting surface 309, namely the first device layer 130 including the first devices 131, remains bonded to the second wafer 200.

By performing the separation step, a portion on the first wafer 100 side is separated from the bonded wafer 300, and the first device layer 130 in the first wafer 100 including the first devices 131 is transferred onto the second wafer 200. By the split at the processed layer 303 in the separation step, a stacked wafer 500 in which the first devices 131 are transferred onto the second wafer 200 is formed. The method for manufacturing the stacked wafer 500 according to the present embodiment has been described above. Meanwhile, as the method for processing the bonded wafer 300, at least the laser processing step and the separation step among the steps described above are performed.

According to the first embodiment described above, the processed layer 303 is formed within the first wafer 100 and split; therefore, necessity of the conventional laser processing to a bonding layer, bonding film, or bonding member may be eliminated. Accordingly, leakage of the light from the laser beam LB emitted at the conventional bonding film or the like does not occur, and damage to the first devices 131 due irradiation with the laser beam LB may be suppressed. Thus, the conventional step to form a thick bonding film is not necessary, and productivity may be improved.

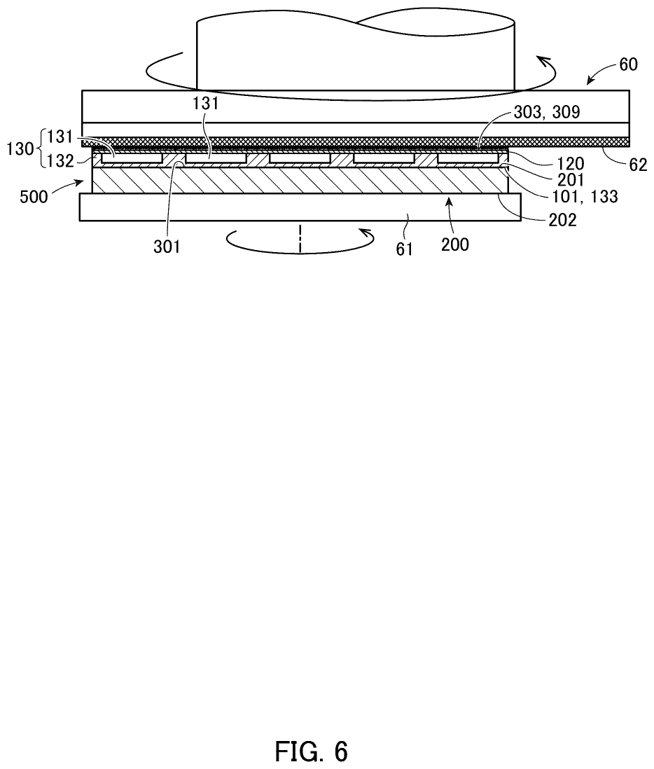

In the method for manufacturing the stacked wafer 500 according to the first embodiment, after the separation step is performed, optionally, a processed-layer treatment step may be performed to planarize the splitting surface 309 of the processed layer 303 on the second wafer 200 side. FIG. 6 is an explanatory diagram of the processed-layer treatment step.

### Processed-Layer Treatment Step

In the processed-layer treatment step performed after the separation step, a polishing apparatus 60 as shown in FIG. 6 performs polish-processing. In this polishing process, wet polishing, CMP, or dry polishing may be performed insofar as the splitting surface 309 of the processed layer 303 is planarized.

In the processed-layer treatment step, the stacked wafer 500 is held on a chuck table 61 of the polishing apparatus 60 such that the back surface 202 of the second wafer 200 faces downward, and thereafter, a polishing pad 62 in the polishing apparatus 60 is placed to face the splitting surface 309 of the processed layer 303 exposed in the separation step. Thereafter, the chuck table 61 and the polishing pad 62 are rotated respectively around vertical axes, and a lower surface of the polishing pad 62 is pressed against the splitting surface 309 of the processed layer 303 exposed in the stacked wafer 500, whereby the splitting surface 309 is polished. As such, irregularities on an upper surface (a surface on the one side in the thickness direction) of the stacked wafer 500 formed of the splitting surface 309 are removed, and the splitting surface 309 is planarized.

Optionally, in the processed-layer treatment step, in place of the above-described polishing process, irregularities on the splitting surface 309 may be removed by plasma etching. By performing the processed-layer treatment step, the planarized surface may be bonded with another wafer having devices for manufacturing a stacked wafer on which the devices are laminated.

Hereinbelow, embodiments of the present disclosure other than the above will be described. In the following description, the same reference numerals may be used for components identical or equivalent to those described in the foregoing embodiments, and explanations thereof may be omitted or simplified.

### Second Embodiment

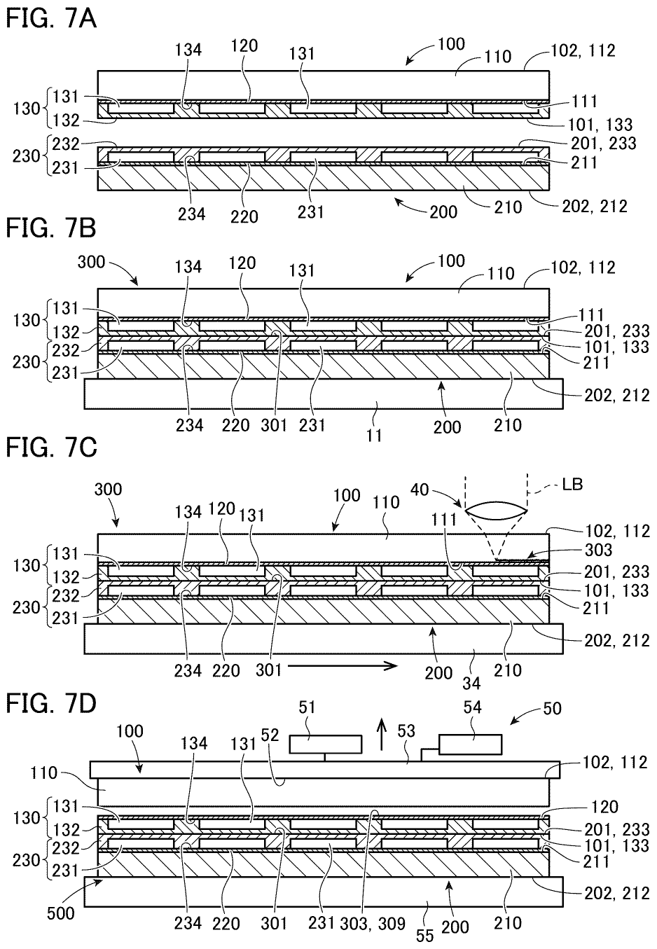

Next, a second embodiment of the present disclosure will be described with reference to FIGS. 7A-7D. FIGS. 7A-7D are explanatory diagrams of steps in a method for manufacturing a stacked wafer according to the second embodiment, where FIG. 7A illustrates a preparation step, FIG. 7B illustrates a bonding step, FIG. 7C illustrates a laser processing step, and FIG. 7D illustrates a separation step. In the second embodiment, the configuration of the second wafer 200 is modified from that in the first embodiment. Note that the steps shown in the drawings for the second embodiment are merely examples and are not limited to this configuration.

The second wafer 200 in the second embodiment is configured in the same manner as the first wafer 100. In this regard, in the second wafer 200, when a component corresponding to that in the first wafer 100 is referred to with the ordinal term “first,” the term “first” is replaced with “second,” and the hundreds digit of the reference numeral is changed from “1” to “2,” and a detailed description thereof will be omitted. As shown in FIG. 7A, the second wafer 200, similarly to the first wafer 100, has second devices 231 (devices) formed on the front surface 201 side.

### Preparation Step

In the preparation step according to the second embodiment, for example, plasma of a rare gas generated by using a rare gas and high-frequency power is emitted at each of the front surface 133 of the first surface film 132 in the first wafer 100 and a front surface 233 of a second surface film 232 in the second wafer 200. As a result, the front surfaces 133, 233 of the first surface film 132 and the second surface film 232 are activated so that the first surface film 132 and the second surface film 232 are enabled to function as bonding members in the bonding step.

### Bonding Step

In the bonding step according to the second embodiment, for placing the first wafer 100 on the second wafer 200 such that the front surface 101, which forms the first device layer 130 side of the first wafer 100, faces the front surface 201, which forms the second device layer 230 side of the second wafer 200, as shown in FIG. 7B, the devices 131, 231 on the first wafer 100 and the second wafer 200, respectively, are aligned with one another in the horizontal direction. Subsequently, the front surface 101 of the first wafer 100 is pressed against the front surface 201 of the second wafer 200, whereby the first surface film 132 of the first wafer 100 and the second surface film 232 of the second wafer 200 that function as bonding members are bonded by plasma-activated bonding. As such, a bonded wafer 300 is formed, and the front surfaces 101, 201 of the first wafer 100 and the second wafer 200 form a bonding surface 301 in the bonded wafer 300.

### Laser Processing Step

In the laser processing step according to the second embodiment, similarly to the first embodiment, the laser beam LB is emitted in pulses toward the bonded wafer 300 from the back surface 102 side of the first wafer 100, as shown in FIG. 7C. The focusing position of the emitted laser beam LB is set within the first wafer 100, as in the first embodiment, and the processed layer 303 is formed planarly, similarly to the first embodiment.

### Separation Step

In the separation step according to the second embodiment, similarly to that in the first embodiment, a force to separate the first wafer 100 from the second wafer 200 is applied to the bonded wafer 300, and the first substrate 110 in the first wafer 100 is split at the second crack 306 in the processed layer 303. As the first wafer 100 side is separated from the bonded wafer 300, the first device layer 130 is transferred to the second wafer 200 such that the first devices 131 on the first wafer 100 are positioned to overlap the second devices 231 on the second wafer 200. Optionally, also in the second embodiment, the processed-layer treatment step may be performed to manufacture a stacked wafer.

### Third Embodiment

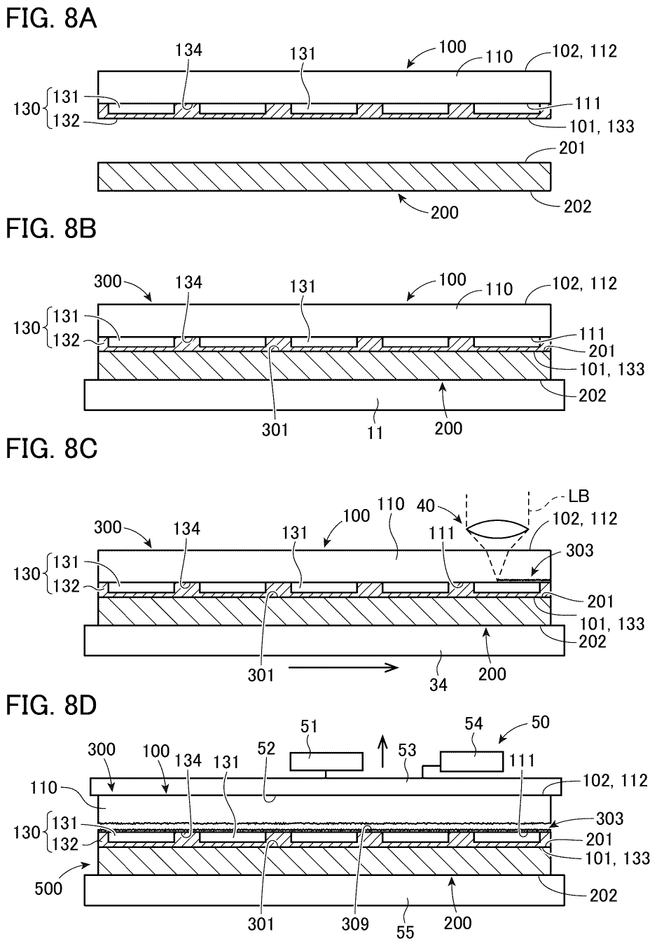

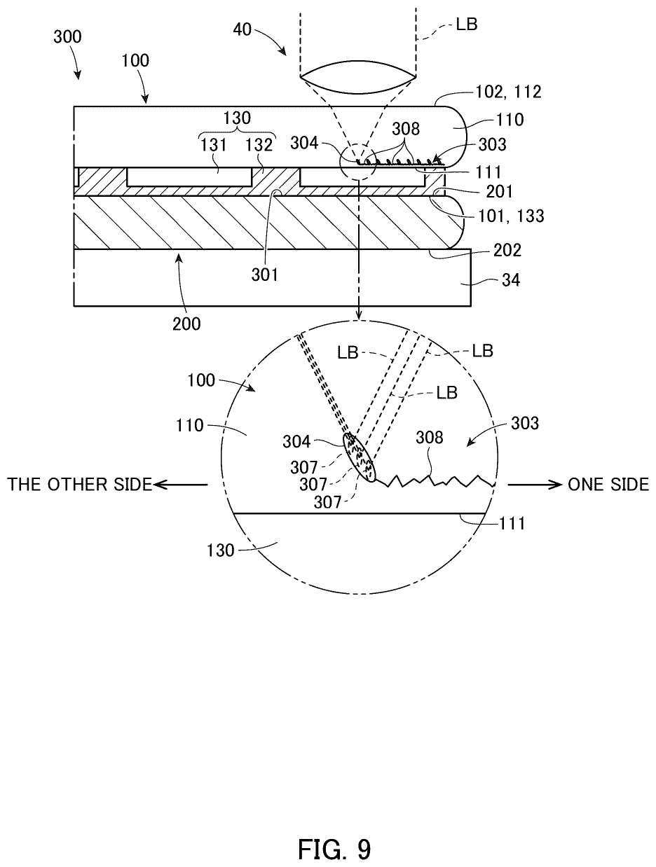

Next, a third embodiment of the present disclosure will be described with reference to FIGS. 8A-8D and FIG. 9. FIGS. 8A-8D are explanatory diagrams of steps in a method for manufacturing a stacked wafer according to the third embodiment, where FIG. 8A illustrates a preparation step, FIG. 8B illustrates a bonding step, FIG. 8C illustrates a laser processing step, and FIG. 8D illustrates a separation step. FIG. 9 is a cross-sectional view illustrating the laser processing step, which is similar to that shown in FIG. 5, according to the third embodiment. In the third embodiment, the configuration of the first wafer 100 is modified from that in the first embodiment.

As shown in FIGS. 8A-8D, the first wafer 100 according to the third embodiment is in a configuration such that the insulating film 120 (see FIGS. 1A-1D) in the first wafer 100 in the first embodiment is not formed. Therefore, in the first wafer 100 according to the third embodiment, the first device layer 130 is formed to be laminated on the front surface 111 of the first substrate 110. Thus, the first devices 131 are formed on the front surface 111 of the first substrate 110.

In the laser processing step according to the third embodiment, the laser emitter 40 emits the laser beam LB having a wavelength transmissive through the first substrate 110 of the first wafer 100 in pulses from the back surface 102 of the first wafer 100 (see FIG. 8C). By being irradiated with this laser beam LB, the planar processed layer 303 is formed within the thickness of the first wafer 100. The processed layer 303 is, as shown in FIG. 9, composed of the processed marks 304, which are formed planarly in the first substrate 110 by the irradiation with the laser beam LB, and a third cracks 308 (cracks), which are developed from the processed marks 304. The third cracks 308 are formed within the thickness of the first substrate 110 so as to connect adjacent processed marks 304, or to connect the processed marks 304 and the outer peripheral edge of the first substrate 110, in a direction parallel to the planar direction of the first substrate 110.

In the laser processing step according to the third embodiment, intervals between adjacent processed marks 304 are set narrower than those in the first embodiment. Accordingly, the third cracks 308 are formed to connect the adjacent processed marks 304 and are developed planarly in the planar direction of the first substrate 110. Although FIG. 9 shows the processed mark 304 in the form of an inclined ellipsoid, optionally, the processed marks 304 may be formed as ellipsoids extending parallel to the planar direction or the thickness direction of the first substrate 110, or as spheres, and the third cracks 308 may be formed to connect the processed marks 304 to one another. The third cracks 308 are formed when the processed marks 304 are formed and portions where the processed marks 304 are formed expand in volume.

In the separation step according to the third embodiment, a force to separate the first wafer 100 from the second wafer 200 is applied to the bonded wafer 300, and the first substrate 110 in the first wafer 100 is split at the processed marks 304 and the third cracks 308 in the processed layer 303.

In this instance in the laser processing step, similarly to the first embodiment, the focusing position for the laser beam LB to form the processed marks 304 is adjusted such that a distance to the front surface 101 is shorter than a distance to the back surface 102 of the first wafer 100. Accordingly, when a thickness of a portion in the first wafer 100 from the split position to the front surface 101 and a thickness of a portion in the first wafer 100 from the split position to the back surface 102 are compared, the thickness of the portion on the front surface 101 side is thinner, and the thickness of the portion on the back surface 102 side is thicker. In the separation step, by splitting in the processed layer 303, the portion of the first wafer 100, having the larger thickness toward the back surface 102 side with respect to the splitting surface 309 is separated from the second wafer 200. Meanwhile, the portion of the first wafer 100, having the smaller thickness toward the front surface 101 side with respect to the splitting surface 309 remains bonded to the second wafer 200 together with the first device layer 130 including the first devices 131.

By performing the separation step, the portion on the first wafer 100 side of the bonded wafer 300 is separated, and the first device layer 130 in the first wafer 100 including the first devices 131 is transferred onto the second wafer 200. In the separation step, by splitting the bonded wafer 300 at the processed marks 304 and the third cracks 308 in the processed layer 303, a stacked wafer 500 in which the first devices 131 are transferred onto the second wafer 200 is formed. According to the third embodiment, by splitting the bonded wafer 300 at the processed marks 304 and the third cracks 308, the small portion of the first substrate 110 remains on the splitting surface 309 side of the stacked wafer 500.

### Fourth Embodiment

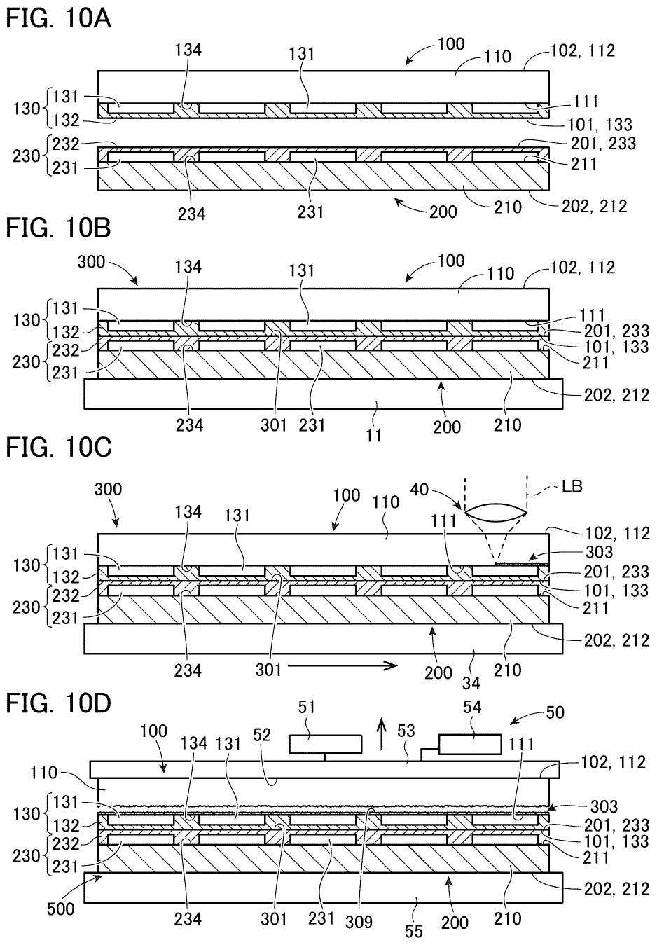

Next, a fourth embodiment of the present disclosure will be described. FIGS. 10A-10D are explanatory diagrams of steps in a method for manufacturing a stacked wafer according to the fourth embodiment. FIG. 10A illustrates a preparation step, FIG. 10B illustrates a bonding step, FIG. 10C illustrates a laser processing step, and FIG. 10D illustrates a separation step.

In the fourth embodiment, the configurations of the wafers 100, 200 are modified from those in the second embodiment. The first wafer 100 according to the fourth embodiment is in a configuration such that the insulating film 120 (see FIGS. 7A-7D) is not formed, similarly to that in the third embodiment. Further, second wafer 200 according to the fourth embodiment is in a configuration such that the insulating film 220 (see FIGS. 7A-7D) is not formed, similarly to first wafer 100.

According to the fourth embodiment, the laser processing step and the separation step may be performed in the same manner as those in the third embodiment. Therefore, even in the first and second wafers 100, 200 having no insulating films 120, 220, such as those in the third and fourth embodiments, necessity of conventional laser processing to a bonding layer, bonding film, or bonding member may be eliminated. As a result, leakage of the light from the laser beam LB emitted at the conventional bonding film or the like does not occur, and damage to the first devices 131 due emission of the laser beam LB may be suppressed. Thus, the conventional step to form a thick bonding film may be eliminated, and productivity may be improved.

### Fifth Embodiment

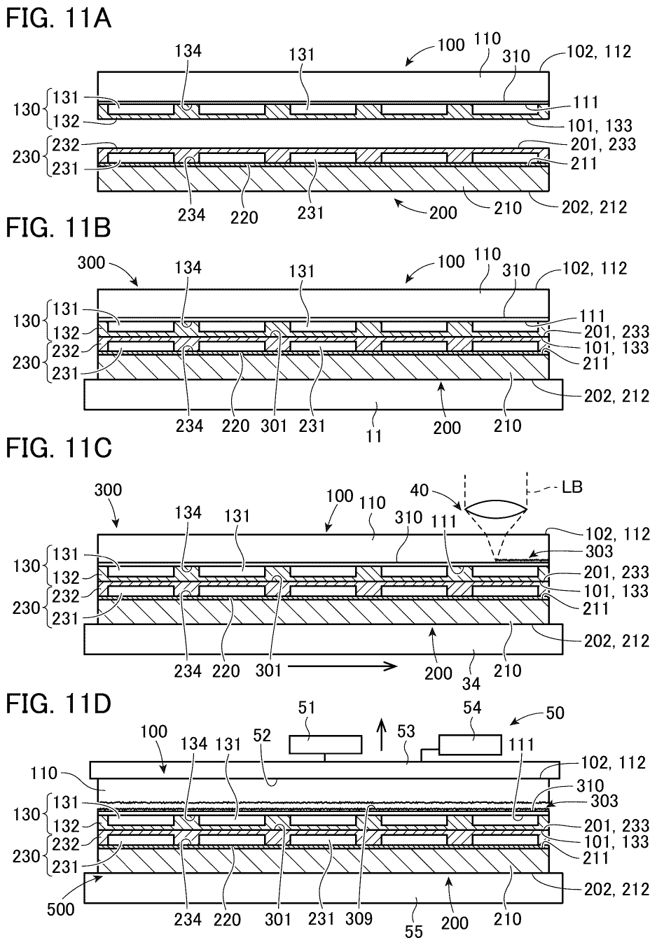

Next, a fifth embodiment of the present disclosure will be described with reference to FIGS. 11A-11D. FIGS. 11A-11C are explanatory diagrams of steps in a method for manufacturing a stacked wafer according to the fifth embodiment, where FIG. 11A illustrates a preparation step, FIG. 11B illustrates a bonding step, FIG. 11C illustrates a laser processing step, and FIG. 11D illustrates a separation step. In the fifth embodiment, the configuration of the first wafer 100 is modified from that in the fourth embodiment.

The first wafer 100 according to the fifth embodiment as shown in FIGS. 11A-11D is in a configuration such that the first wafer 100 includes a light-blocking film 310 in place of the insulating film 120 in the first wafer 100 shown in FIGS. 7A-7D in the second embodiment. Optionally, although not illustrated, the light-blocking film 310 may be provided between the insulating film 120 and the first device layer 130 in the first wafer 100 shown in FIGS. 7A-7D in the second embodiment, or between the first device layer 130 and the first substrate 110 in the first wafer 100 shown in FIGS. 10A-10D of the fourth embodiment. As shown in FIGS. 11A and 11B, the light-blocking film 310 is provided planarly within the first substrate 110 of the first wafer 100 at a position in proximity to the front surface 111.

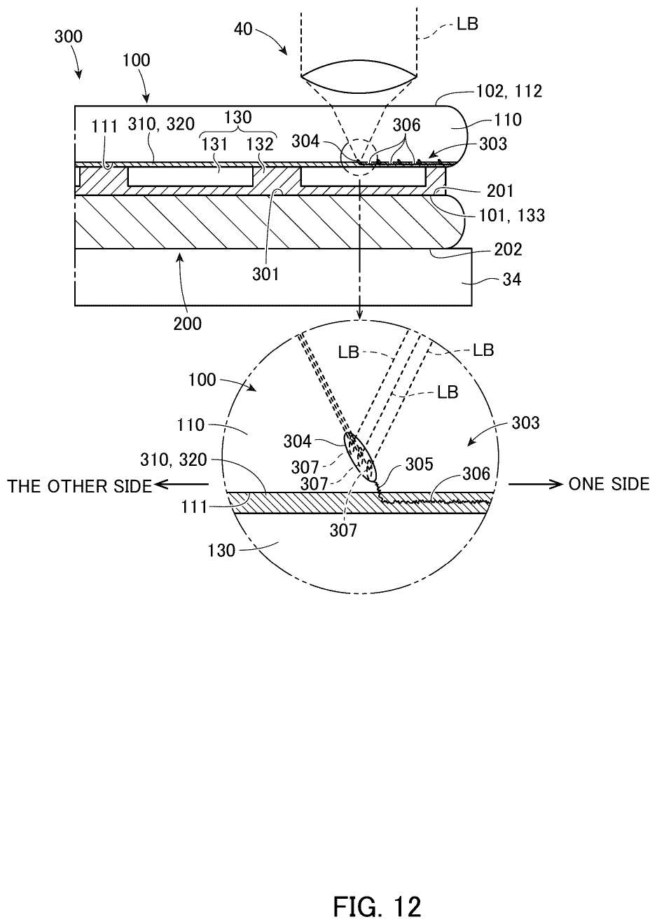

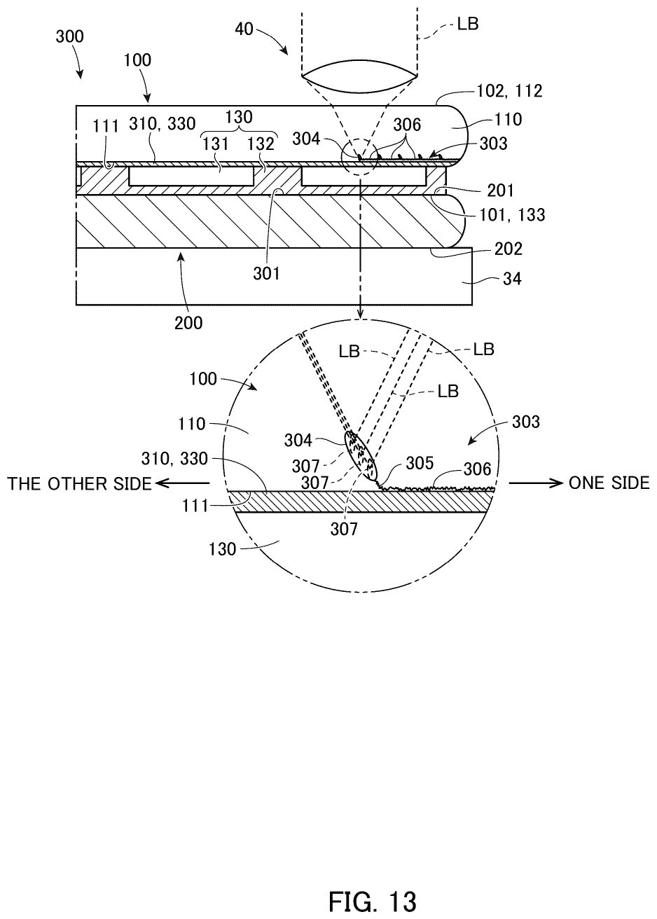

The light-blocking film 310 functions to block the light leaked through the first substrate 110 when the laser beam LB is emitted and focused in the first substrate 110 to form the processed marks 304 in the laser processing step, and is formed of a porous film 320 such as a porous oxide film or nitride film (see FIG. 12) or a metal film 330 (see FIG. 13). FIGS. 12 and 13 are cross-sectional views illustrating a laser processing step, which is similar to that shown in FIG. 5, according to the fifth embodiment. Note that, in FIGS. 12 and 13, illustration of the insulating film 220 and the second device layer 230 in the second wafer 200 is omitted.

For forming the light-blocking film 310 of the porous film 320, silicon in the first substrate 110 is made porous by an anodization reaction and thereafter by gas oxidation. In the case where the light-blocking film 310 is the porous film 320, a bonding strength in the porous film 320 is less than the bonding strength in the first substrate 110. Therefore, as shown in the enlarged view in FIG. 12, when the laser beam LB is focused to form the processed mark 304 in the first substrate 110, the first crack 305 is formed from the processed mark 304 toward the porous film 320 in the thickness direction of the first substrate 110. When the lower end of the first crack 305 reaches the porous film 320, the second crack 306 is developed in the horizontal direction within the porous film 320 and formed planarly.

For forming the light-blocking film 310 of the metal film 330, the light-blocking film 310 may be formed of, for example, a material such as aluminum or nickel, by vapor deposition or sputtering. In the case where the light-blocking film 310 is the metal film 330, as shown in the enlarged view of FIG. 13, the laser beam LB is focused to form the processed mark 304 in the first substrate 110, and the first crack 305 is formed from the processed mark 304. When the lower end of the first crack 305 reaches a boundary with the metal film 330, the second crack 306 is developed along the boundary between the first substrate 110 and the metal film 330, thereby forming the second crack 306 planarly.

By forming the light-blocking film 310 in the first wafer 100, even if leakage of the light from the laser beam LB passing through the processed layer 303 occurs, the light-blocking film 310 may block the leaked light. Accordingly, damage to the devices 131, 231 may be suppressed effectively, and the conventional step to form a thick bonding film may be eliminated; therefore, productivity may be improved. Note that the wafers 100, 200 according to the fifth embodiment may be in configurations such that the insulating films 120, 220 (see FIGS. 7A-7D) are formed therein, respectively, similarly to those in the second embodiment, the same processes as described above may be performed. In the case where the light-blocking film 310 is formed of the metal film 330, the metal film 330 blocking the leaked light may be irradiated with the leaked light and heated. As a result, the metal film 330 may thermally expand, which may provide an effect such that the first substrate 110 is separated easily.

Note that embodiment of the present disclosure is not necessarily limited to the configuration described above but may be modified in various ways. In the embodiments described above, sizes or forms of the components illustrated in the accompanying drawings are not limited thereto but may be modified optionally within the scope of the effects of the present disclosure. Moreover, the embodiment may be modified optionally without departing from the scope of the object of the present disclosure.

For example, for forming the processed marks 304 as described above in the processed layer 303, the laser beam LB may not necessarily be split to irradiate the plurality of focusing positions 307. Rather, for example, the laser beam LB, of which focusing position 307 has a width in the extending direction of the processed mark 304, may be emitted, or the laser beam LB may be dividedly emitted in a plurality of times along the extending direction of the processed mark 304 to irradiate the plurality of focusing positions 307.

For another example, the processed marks 304 in the planar processed layer 303 are not necessarily limited to the shapes in the view from above as shown in FIGS. 3A-3B and 4A-4D, but may be modified. For example, the processed marks 304 may be formed to radiate in a plurality of linear directions from the center of the first wafer 100. Such processed marks 304 may be formed to extend from an outer periphery, which is one side in the planar direction of the first wafer 100, toward the center of the first wafer 100, which is the other side in the planar direction, by emitting the laser beam LB in the laser processing step.

For another example, after performing the processed-layer treatment step described above, another wafer may be further laminated on the splitting surface 309 of the processed layer 303 in the stacked wafer 500, and devices may be transferred thereon. In this case, the planarized splitting surface 309 in the processed layer 303 and one of the surfaces of the another wafer to be laminated may be activated in the same manner as described above and may be bonded by activating and joining these surfaces. Further, by performing the laser processing step and the separation step as described above on this wafer, devices of further another wafer may be transferred onto the stacked wafer 500. Moreover, such transfer of devices may further be repeated.

As described above, the present disclosure is effective in that a processed layer may be formed planarly within a first wafer of a bonded wafer to be split and separated, thereby eliminating the need to form a thick bonding film and improving productivity.

What is claimed is:

1. A method for processing a bonded wafer, the bonded wafer including a first wafer on which a first device is formed on a front surface side of a first substrate thereof and a second wafer bonded together, to transfer the first device to the second wafer by separating a first substrate side of the bonded wafer therefrom, the method comprising:
a laser processing step including forming a processed layer planarly within the first wafer by emitting a laser beam having a wavelength transmissive through the first substrate toward the bonded wafer from a back surface of the first wafer to be focused within the first substrate at a position in vicinity of a bonded surface between the first wafer and the second wafer; and
a separation step including separating the first substrate side from the second wafer by splitting at the processed layer, with the first device from the first wafer remaining bonded to the second wafer.

2. The method according to claim 1,
wherein the first wafer includes an insulating film formed planarly between the front surface of the first substrate and the first device,
wherein the processed layer includes a processed mark formed planarly within the first substrate by irradiation with the laser beam, a first crack developed from the processed mark toward the insulating film in a thickness direction of the first substrate, and a second crack developed planarly from the first crack reaching the insulating film along a planar direction of the first substrate, and
wherein the bonded wafer is split at the second crack in the separation step.

3. The method according to claim 1,
wherein the processed layer includes a processed mark formed planarly within the first substrate by irradiation with the laser beam, and a second crack formed within the first substrate and connecting the processed mark and an adjacent processed mark in a direction parallel to a planar direction of the first substrate, and
wherein the bonded wafer is split at the processed marks and the second crack in the separation step.

4. The method according to claim 1, wherein the second wafer includes a second device formed on a front surface side thereof.

5. The method according to claim 1, further includes, after the separation step, a processed-layer treatment step including planarizing a splitting surface formed on a side of the second wafer.

6. The method according to claim 2, wherein the laser processing step includes forming the processed mark that extends from a non-bonded surface opposite to the bonded surface in the first wafer toward the bonded surface, obliquely toward one side from the other side in a planar direction of the bonded surface.

7. The method according to claim 1, wherein the laser processing step includes forming the processed layer planarly from one side toward the other side in a planar direction of the first wafer.

8. The method according to claim 7, wherein the laser processing step includes forming the processed layer planarly such that a processed mark is formed from an outer periphery of the first wafer being the one side toward a center of the first wafer being the other side in a plurality of concentric circles or swirly centered on the center of the first wafer, or in a plurality of lines.

9. The method according to claim 7, wherein the laser processing step includes forming the processed layer planarly such that a processed mark is formed in a plurality of lines from one side on a diameter of the first wafer being the one side toward the other side on the diameter of the first wafer being the other side.

10. The method according to claim 1, wherein the first wafer to be irradiated with the laser beam includes a light-blocking film configured to block leaked light from the laser beam between the processed layer formed in the laser processing step and the bonded surface.

11. The method according to claim 10, wherein the light-blocking film is a porous film.

12. The method according to claim 10, wherein the light-blocking film is a metal film.

13. The method according to claim 3, wherein the laser processing step includes forming the processed mark that extends from a non-bonded surface opposite to the bonded surface in the first wafer toward the bonded surface, obliquely toward one side from the other side in a planar direction of the bonded surface.

14. The method according to claim 2, wherein the laser processing step includes forming the processed layer planarly from one side toward the other side in a planar direction of the first wafer.

15, The method according to claim 3, wherein the laser processing step includes forming the processed layer planarly from one side toward the other side in a planar direction of the first wafer.

16. The method according to claim 4, wherein the laser processing step includes forming the processed layer planarly from one side toward the other side in a planar direction of the first wafer.

17. The method according to claim 5, wherein the laser processing step includes forming the processed layer planarly from one side toward the other side in a planar direction of the first wafer.

18. The method according to claim 2, wherein the laser processing step includes forming the processed layer planarly such that the processed mark is formed from an outer periphery of the first wafer being the one side toward a center of the first wafer being the other side in a plurality of concentric circles or swirly centered on the center of the first wafer, or in a plurality of lines.

19. The method according to claim 7, wherein the laser processing step includes forming the processed layer planarly such that the processed mark is formed in a plurality of lines from one side on a diameter of the first wafer being the one side toward the other side on the diameter of the first wafer being the other side.
